(19) United States
(12) Patent Application Publication
(10) Pub. No.: US 2008/0150077 A1
(43) Pub. Date: Jun. 26, 2008

(54) Semiconductor Device and Fabricating Method Thereof

(76) Inventor: JAE WON HAN, Suwon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/863,422

(22) Filed: Sep. 28, 2007

(30) Foreign Application Priority Data
Dec. 21, 2006 (KR) 10-2006-0131528

(51) Int. Cl. H01L 29/00; H01L 21/02

(52) U.S. Cl. 257/532; 438/397; 257/E29.001; 257/E21.011

(57) ABSTRACT

Disclosed is a semiconductor device comprising a first substrate having a through-electrode and a capacitor cell, a second substrate having a circuit unit, and a connection electrode electrically connecting the capacitor cell with the circuit unit.

### CROSS-REFERENCE TO RELATED APPLICATION

The present application claims the benefit under 35 U.S.C. §119 of Korean Patent Application No. 10-2006-0131528, filed Dec. 21, 2006, which is hereby incorporated by reference in its entirety.

### BACKGROUND

Various capacitor structures, such as a Polysilicon to Polysilicon capacitor structure, a Polysilicon to Silicon capacitor structure, a Metal to Silicon capacitor structure, a Metal to Polysilicon capacitor structure, and a Metal to Metal capacitor structure, have been employed as capacitor structures for highly integrated semiconductor devices.

Among the above capacitor structures, the Metal to Metal capacitor structure, or a Metal Insulator Metal (MIM) structure, has a low series resistance, so the MIM structure is being extensively used for capacitors having high capacitance.

Since the MIM capacitor is provided between metal interconnections, an upper electrode layer or a lower electrode layer of the MIM capacitor may be damaged during the fabricating process of the MIM capacitor, so the defect rate is increased and the yield rate of products is lowered.

In addition, in the process of forming the capacitor, since a thickness of an insulating layer is fixed and a space for controlling an area of the metal electrode is limited, a required capacitance value may not be easily obtained.

### BRIEF SUMMARY

Accordingly, embodiments of the present invention provide a semiconductor device and a method of fabricating the same, capable of simplifying a fabricating process and improving the fabricating efficiency.

A semiconductor device according to an embodiment comprises a first substrate having a through-electrode and a capacitor cell, a second substrate having a circuit unit, and a connection electrode electrically connecting the capacitor cell with the circuit unit.

A method of fabricating a semiconductor device according to an embodiment comprises preparing a first substrate having a through-electrode and a capacitor cell, preparing a second substrate having a circuit unit including a transistor and an interconnection, stacking the first substrate on the second substrate, and electrically connecting the capacitor cell with the circuit unit.

### BRIEF DESCRIPTION OF THE DRAWINGS

FIG. 1 is a plan view representing a semiconductor substrate having a capacitor cell fabricated according to an embodiment of the present invention.

FIG. 2 is a cross-sectional view schematically representing a substrate having a capacitor cell fabricated according to an embodiment of the present invention.

FIG. 3 is a cross-sectional view schematically representing a substrate having a circuit unit fabricated according to an embodiment of the present invention.

FIG. 4 is a cross-sectional view schematically representing a semiconductor device having a capacitor fabricated according to an embodiment of the present invention.

FIGS. 5 and 6 are plan views representing examples of substrates on which various capacitors having capacitances different from each other are formed according to certain embodiments of the present invention.

FIGS. 7 to 12 are cross-sectional views of a process of fabricating a substrate having a through electrode and a capacitor according to an embodiment of the present invention.

### DETAILED DESCRIPTION

In the description of embodiments, it will be understood that when a layer (or film), a region, a pad, a pattern or a structure are referred to as being ‘on/above’ another layer, region, pad, pattern or substrate, it can be directly on another layer, region, pad, pattern or substrate, or one or more intervening layers, regions, pads, patterns or structures may also be present. Further, it will be understood that when a layer (or film), a region, a pad, a pattern or a structure are referred to as being ‘below/under’ another layer, region, pad, pattern or substrate, it can be directly tinder layer, region, pad, pattern or substrate, and one or more intervening layers, regions, pads, patterns or structures may also be present. In addition, it will also be understood that when a layer (or film), a region, a pad, a pattern or a structure are referred to as being ‘between’ two layers, two regions, two pads, two patterns or two structures, it can be the only layer, region, pad, pattern or structure between the two layers, the two regions, the two pads, the two patterns and the two structures or one or more intervening layers, regions, pads, patterns or structures may also be present. Thus, the meaning thereof must be determined based on the scope of the present invention.

Hereinafter, an embodiment of the present invention will be described in detail with reference to the accompanying drawings.

A method is provided of effectively fabricating a semiconductor device having a capacitor, in which a first substrate having a capacitor cell and a second substrate having a circuit unit are separately manufactured, and then the first substrate is stacked on the second substrate. The capacitor cell formed on the first substrate is electrically connected with the circuit unit formed on the second substrate through a connection electrode. The capacitor cell refers to a region in which an upper electrode and a lower electrode that constitute a capacitor are formed. A stacked layer including the upper electrode/an insulating layer/a lower electrode can be formed in the capacitor cell.

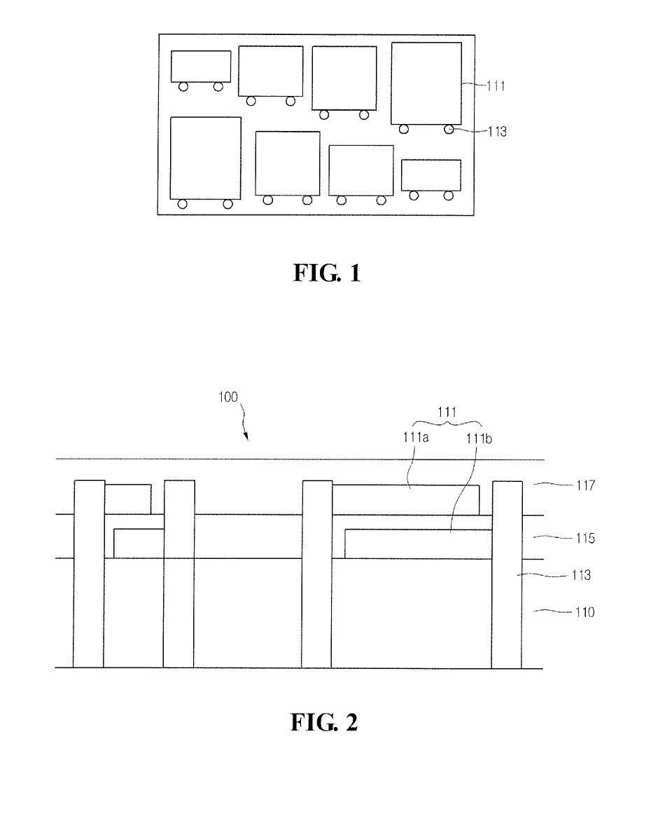

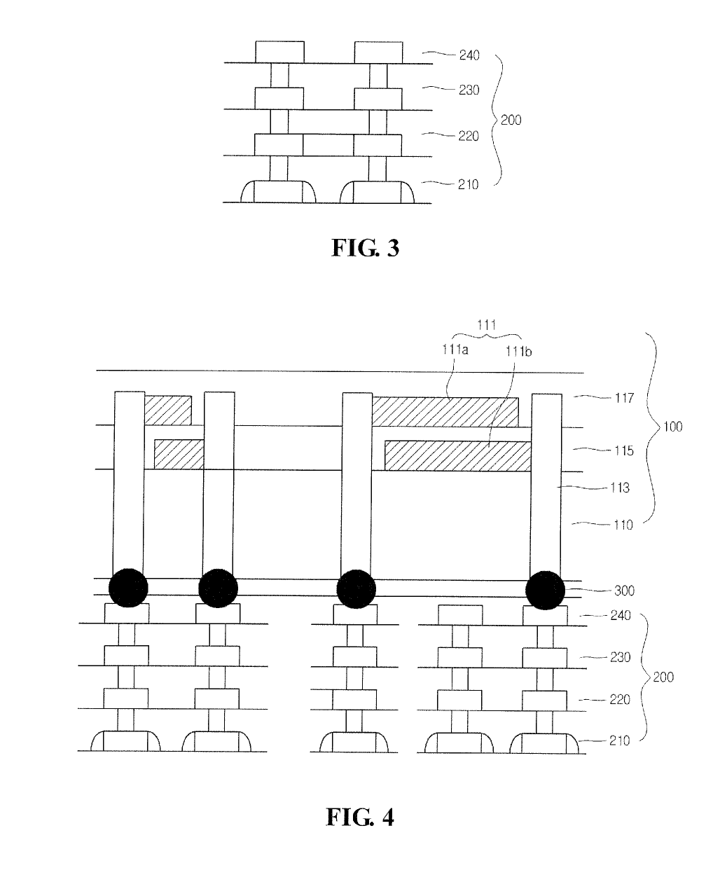

FIG. 1 is a plan view representing a substrate having a capacitor cell fabricated according to an embodiment of a method of fabricating a semiconductor device, and FIG. 2 is a cross-sectional view schematically representing the substrate having the capacitor cell fabricated according to an embodiment.

As shown in FIGS. 1 and 2, the first substrate 100 including a capacitor cell 111 and a through-electrode 113 can be manufactured. The capacitor cell 111 can include an upper electrode 111a and a lower electrode 111b. A through-electrode 113 can be connected with the upper electrode 111a and another through-electrode can be connected with the lower electrode 111b of the capacitor cell 111. The position of the through-electrodes 113 can be changed as needed.

Hereinafter, a process of fabricating the first substrate 100 according to an embodiment will be briefly described.

Referring to FIG. 2, a lower electrode 111b, an insulating layer 115 and an upper electrode 111a are formed on a semiconductor substrate 110. Another insulating layer (not shown) may be formed between the semiconductor substrate 110 and the lower electrode 111b.

In addition, the through-electrode 113 can be connected with the capacitor cell 111 by passing through the semiconductor substrate 110. The through-electrode 113 can be formed by sequentially performing a patterning process, an etching process, a metallization process and a CMP (Chemical Mechanical Polishing) process relative to the semiconductor substrate 110. The above processes are generally known in the art and are not the subject matter of the embodiment, so detailed description thereof will be omitted.

The through-electrode 113, the upper electrode 111a and the lower electrode 111b can each be formed of tungsten (W), copper (Cu), aluminum (Al), silver (Ag), gold (Au), or a combination thereof. The capacitor cell 111 and the through-electrode 113 can be formed through, for example, a CVD (Chemical Vapor Deposition) process, a PVD (Physical Vapor Deposition) process, an Evaporation process, or an ECP (Electrochemical Plating) process. In addition, materials such as TaN, Ta, TiN, Ti or TiSiN may be used for a barrier metal for the capacitor cell 111 and the through-electrode 113. The barrier metal can be formed through, for example, a CVD process, a PVD process, or an ALD (Atomic Layer Deposition) process.

Then, a protective layer 117 can be formed on the capacitor cell 111.

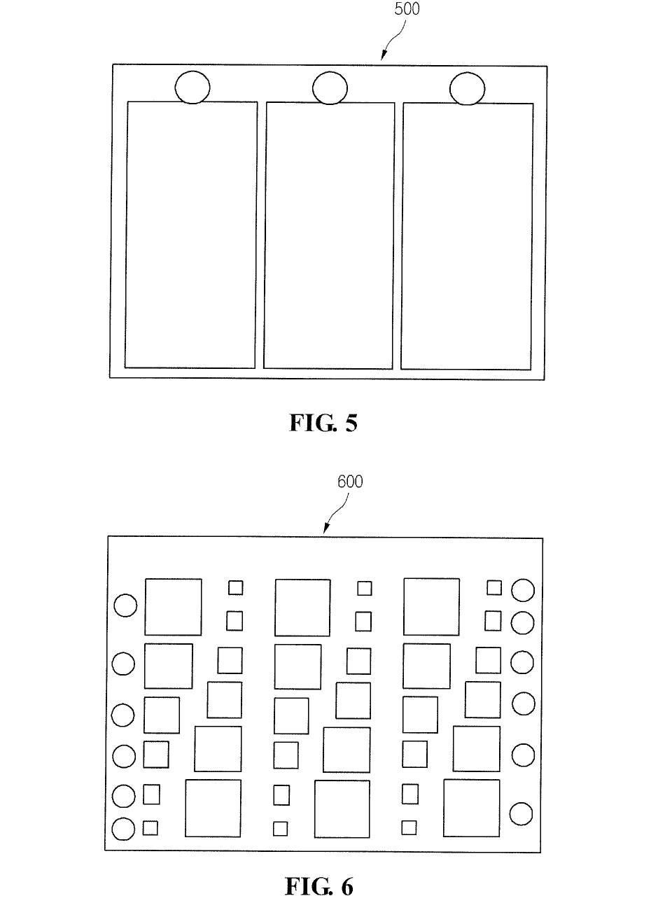

FIG. 3 is a view schematically representing the substrate having a circuit unit fabricated according to an embodiment.

As shown in FIG. 3, a second substrate 200 including a transistor layer 210, a first metal layer 220, a second metal layer 230 and a third metal layer 240 can be fabricated.

The transistor layer 210 and the first metal layer 220, the second metal layer 230, and the third metal layer 240 form the circuit unit for processing signals. Although three metal layers are described, the number of metal layers can be changed according to the design of the semiconductor device.

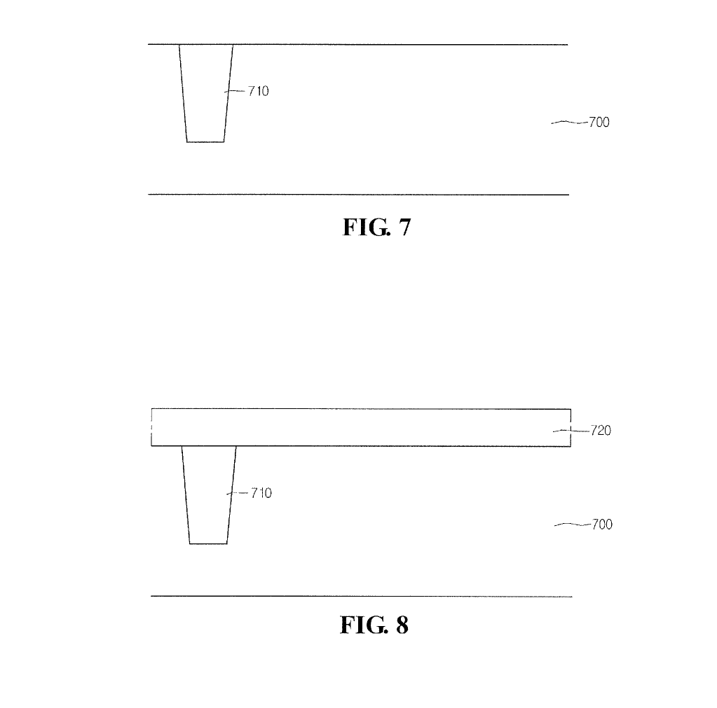

After fabricating the first substrate 100 and the second substrate 200, the first substrate 100 and the second substrate 200 can be stacked. FIG. 4 is a view schematically representing a semiconductor device having the stacked structure according to an embodiment of the present invention.

As shown in FIG. 4, a semiconductor device having the capacitor includes the first substrate 100, the second substrate 200 and a connection electrode 300. The connection electrode 300 connects the capacitor cell 111 on the first substrate 100 with the circuit unit on the second substrate 200 when the first substrate 100 is stacked on the second substrate 200. The connection electrode 300 can be electrically connected with the capacitor cell 111 by means of the through-electrodes 113 formed on the first substrate 100. The connection electrode 300 is also connected with an uppermost electrode of the second substrate, such as, for example a third metal layer 240 of the circuit unit.

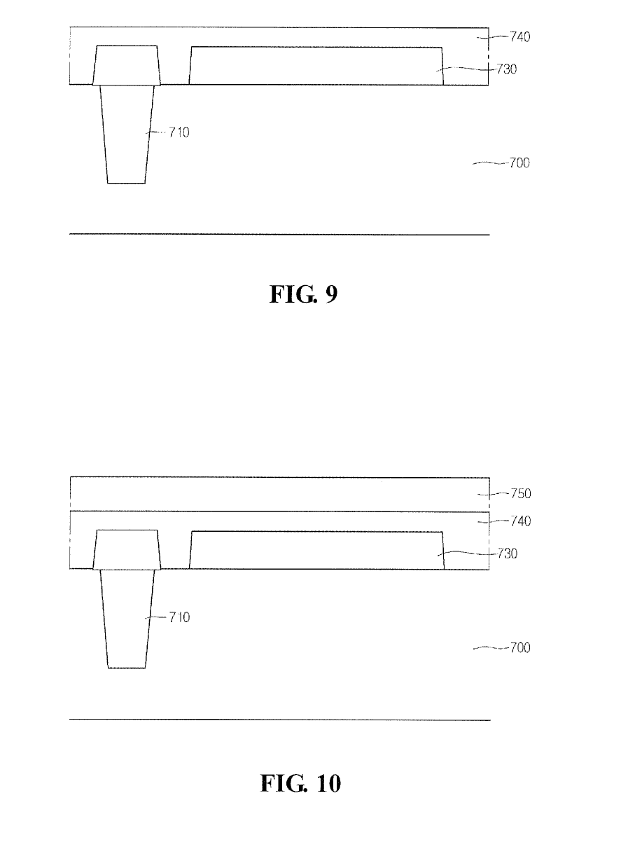

FIGS. 5 and 6 are views schematically representing examples or capacitor-electrode layers 500 and 600, respectively, on which various capacitors having capacitances different from each other are fabricated.

As shown in FIGS. 5 and 6, various capacitor electrodes having capacitances different from each other can be designed on a single substrate, so that a capacitor library can be provided.

FIG. 5 shows a plan view of a layer 500 for lower electrodes of the capacitor, and FIG. 6 shows a plan view of a layer 600 for upper electrodes of the capacitor. In an embodiment, the lower electrode 111b can be fabricated using 1 to 10 wide metal plates. Since the lower electrode 111b may be used as a common electrode, the lower electrode 111b uses a plate that has an area wider than that of an upper electrode 111a provided as a plurality of sections. When the capacitor is to be connected in series or in a row, the lower electrode 111b of the capacitor can be divided into 2 to 10 sections to provide various combinations.

The tipper electrode 111a may be designed to have a number of electrodes of various areas such that the capacitor can be prepared in the form of a capacitor library. Some of the connection wires are not shown. The number of the upper electrodes 111a can be changed according to the area and the purpose for the capacitor cells.

An electrode and an interconnection can be designed such that the through-electrode 113 is placed in a scribe lane. A circuit region, on which the circuit is formed, and the scribe lane, which divides the circuit regions into each circuit region can be defined on the semiconductor device. According to an embodiment, a semiconductor substrate 110 having a plurality of circuit regions where circuits are formed and scribe lanes that divide the circuit regions is prepared. Then, the circuit unit is formed on the circuit region of the semiconductor substrate, and the through-electrode 113 is formed on the scribe lane.

If necessary, the through-electrode and an interconnection for a through-electrode and the upper electrode and a through-electrode and the lower electrode may be provided as a multi-metal layer, for instance, using two or three metal layers.

The shape of the upper electrode/the lower electrode of the capacitor is not limited to that shown in FIGS. 5 to 6, and the upper electrode/the lower electrode of the capacitor may have various shapes, such as, for example, a circle, a square, a triangle or a polygon. In addition, the cross-section of a through-electrode may have various shapes, such as, for example, a circle, a square, a triangle or a polygon.

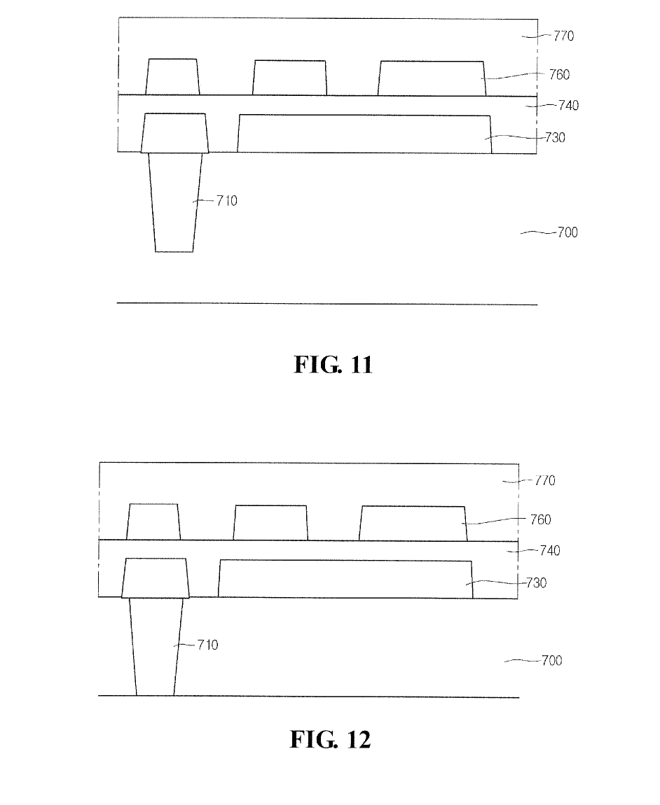

FIGS. 7 to 12 are views for explaining the processes of fabricating the substrate having the through-electrode and the capacitor according to an embodiment of the present invention.

Referring to FIG. 7, a bottom portion of a through-electrode 710 having a first depth can be formed on a semiconductor substrate 700.

In one embodiment, a silicon wafer may be used as the semiconductor substrate 700. However, since the semiconductor substrate 700 serves to form the capacitor only, a wafer having high quality and high price is not necessary.

The bottom portion of the through-electrode 710 can have a depth of 50 μm to 500 μm, and may have a Critical Dimension (CD) of about 1 μm to 10 μm. The bottom portion of the through electrode 710 can be formed to such a depth by an etching process of the substrate.

The through-electrode 710 may include a barrier metal. The barrier metal can be formed of a thin metal film, such as, for example, Ti, TiN, Ti/TiN, Ta, Ta/N, Ta/TaN, Ta/TaN, TiSiN, TaSiN, Co, Co compound, Ni, Ni compound, W, W compound, or nitride.

A metal layer deposition process, such as PVD, Sputtering, Evaporation, Laser Ablation, ALD or CVD can be used to form the barrier metal. The barrier metal may have a thickness of about 20 Å to 1000 Å.

A metal layer for forming the through-electrode 710 can be one selected from the group consisting of W, Cu, Al, Ag, Au, and a mixture thereof. The metal layer can be formed by PVD, Sputtering, Evaporation, Laser Ablation, ALD or CVD. In an embodiment, the metal layer may be deposited to a thickness of about 50 μm to 900 μm.

Then, the metal layer, which is deposited on the semiconductor substrate 700, is removed from regions where a through-electrode is not to be formed, thereby forming the through-electrode 710. In order to remove the metal layer deposited on the semiconductor substrate 700, a CMP process or an Etch Back process may be employed. The CMP or etch back process can also be performed to remove a barrier metal.

Referring to FIG. 8, a first metal layer 720 can be formed on the through-electrode 710 to be used for patterning the lower electrode of the capacitor.

For instance, the first metal layer 720 may include Al, a metal mixed with Al and Cu, a metal mixed with Al and Si, or a metal mixed with Al, Si and Cu. In addition, the first metal layer 720 may include Ti/TiN/Al/Ti/TiN or a mixture of Ti/TiN/Al/Ti/TiN.

The first metal layer 720 can have a thickness of about 500 Å to 10,000 Å similar to the thickness of the metal for forming the lower electrode of the capacitor. The first metal layer 720 can be formed by, for example, a CVD process or a PVD process.

Referring to FIG. 9, a patterning process can be performed relative to the first metal layer 720 to form the lower electrode 730 of the capacitor, and an insulating layer 740 can be formed on the patterned lower electrode 730. A portion of the first metal layer 720 remains on the through-electrode 710 to begin building tip an upper portion of the through-electrode 710.

The insulating layer 740 can be, for example, SiO₂, BPSG, TEOS, SiN or a Low-k material obtained by using various sources. The insulating layer 740 can have a thickness of about 1000 Å to 15,000 Å. The insulating layer 740 can be formed by means of an electrical furnace, CVD or PVD. Then, a polishing process, such as CMP can be performed relative to the insulating layer 740. In one embodiment, the CMP process is performed until the insulating layer 740 has a thickness of about 5 Å to 5000 Å corresponding to the predetermined capacitance of the capacitor.

Referring to FIG. 10, a second metal layer 750 to be used for patterning the upper electrode of the capacitor can be formed on the insulating layer 740.

For instance, the second metal layer 750 may include Al, a metal mixed with Al and Cu, a metal mixed with Al and Si, or a metal mixed with Al, Si and Cu. In addition, the second metal layer 750 may include Ti/TiN/Al/Ti/TiN or a mixture of Ti/TiN/Al/Ti/TiN.

The second metal layer 750 can have a thickness of about 500 Å to 10,000 Å similar to the thickness of the metal for forming the upper electrode of the capacitor. The second metal layer 750 can be formed by a CVD process or a PVD process.

Referring to FIG. 11, a patterning process can be performed relative to the second metal layer 720 so as to form the upper electrode 760 of the capacitor. Then a protective layer 770 can be formed on the patterned upper electrode 760.

The protective layer 770 can include SiO₂, BPSG, TEOS or SiN material obtained by using various sources. The protective layer 770 can have a thickness of about 0.8 μm to 6 μm. The protective layer 770 can be formed by means of an electrical furnace, CVD, or PVD. After forming the protecting layer, a polishing process, such as CMP, can be performed relative to the protective layer 770, until the protective layer 770 has a thickness of about 0.5 μm to 5 μm.

Referring to FIG. 12, a polishing process can be performed relative to the bottom surface of the semiconductor substrate 700 such that the through-electrode 710 is exposed below the semiconductor substrate 700.

The CMP process or a back grind process may be employed as the polishing process. In one embodiment, the semiconductor substrate 700 can have a thickness of about 50 μm to 500 μm after the polishing process.

In an embodiment, a semiconductor device with a capacitor as described above can be used in a system in a package (SiP).

Since the fabricating process for forming the first substrate having the capacitor cell is performed separately from the fabricating process for forming the second substrate having the transistor and the metal interconnection, the second substrate having the transistor and the metal interconnection does not need to be discarded even when error occurs during the fabricating process for forming the first substrate having the capacitor cell.

In addition, the substrate having the capacitor cell is separately manufactured, so that the capacitor can be provided in the form of a library.

The process for the capacitor cell is performed separately from the process for the transistor and the metal interconnection, so that the circuit unit rarely receives an influence from the process for the capacitor cell.

As described above, according embodiments of the semiconductor device and the method of fabricating the same, the fabricating process is simplified and the fabricating efficiency is improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a first substrate comprising a through-electrode and a capacitor cell;
a second substrate comprising a circuit unit including a transistor and an interconnection, wherein the first substrate is on the second substrate; and
a connection electrode electrically connecting the capacitor cell with the circuit unit.

2. The semiconductor device according to claim 1, wherein the capacitor cell is formed on a semiconductor substrate of the first substrate, and the through-electrode connects with the capacitor cell and passes through the semiconductor substrate.

3. The semiconductor device according to claim 1, wherein the through-electrode is formed on a scribe lane of the first substrate.

4. The semiconductor device according to claim 1, wherein the connection electrode is electrically connected with the capacitor cell by means of the through-electrode.

5. The semiconductor device according to claim 1, wherein the transistor is formed on a semiconductor substrate of the second substrate, and the interconnection is formed of a metal layer above the transistor.

6. The semiconductor device according to claim 1, wherein the capacitor cell comprises an electrode comprising at least one material selected from the group consisting of W, Cu, Al, Ag, and Au.

7. The semiconductor device according to claim 1, wherein the through-electrode comprises at least one material selected from the group consisting of W, Cu, Al, Ag, and Au.

8. The semiconductor device according to claim 1, wherein the through-electrode comprises a barrier metal, and wherein the barrier metal comprises at least one material selected from the group consisting of Ti, TiN, Ti/TiN, Ta, Ta/N, Ta/TaN, Ta/TaN, TiSiN, TaSiN, Co, Co compound, Ni, Ni compound, W, W compound, and nitride.

9. A method of fabricating a semiconductor device, comprising:
preparing a first substrate comprising a through-electrode and a capacitor cell;
preparing a second substrate comprising a circuit unit including a transistor and an interconnection;
stacking the first substrate on the second substrate; and
electrically connecting the capacitor cell with the circuit unit.

10. The method according to claim 9, wherein electrically connecting the capacitor cell with the circuit unit comprises providing a connection electrode on the second substrate, wherein upon stacking the first substrate on the second substrate, the capacitor cell is electrically connected with the circuit unit through the connection electrode.

11. The method according to claim 9, wherein the connection electrode is electrically connected with the capacitor cell by means of the through-electrode.

12. The method according to claim 9, wherein forming the first substrate comprises:
forming the through-electrode having a first depth on a semiconductor substrate;
forming a capacitor lower electrode on the semiconductor substrate having the through-electrode, wherein the capacitor lower electrode is electrically connected with the through-electrode;
forming an insulating layer on the capacitor lower electrode;
forming a capacitor upper electrode on the insulating layer; and
polishing a lower surface of the semiconductor substrate to expose the through-electrode.

13. The method of claim 12, further comprising forming a protective layer on the insulating layer and the capacitor upper electrode.

14. The method of claim 12, wherein the through-electrode is formed to a depth of about 50 μm to about 500 μm, and wherein the through-electrode is formed with a critical dimension (CD) of about 1 μm to about 10 μm.

15. The method according to claim 12, wherein the insulating layer comprises at least one material selected from the group consisting of SiO₂, BPSG, TEOS, and SiN.

16. The method according to claim 9, wherein the capacitor cell comprises an electrode comprising at least one material selected from the group consisting of W, Cu, Al, Ag, and Au.

17. The method according to claim 9, wherein the through-electrode comprises at least one material selected from the group consisting of W, Cu. Al, Ag, and Au.

18. The method according to claim 9, wherein the through-electrode is formed on a scribe lane.

19. The method according to claim 9, wherein the through-electrode comprises a barrier metal, and wherein the barrier metal comprises at least one material selected from the group consisting of Ti, TiN, Ti/TiN, Ta, Ta/N, Ta/TaN, Ta/TaN, TiSiN, TaSiN, Co, Co compound, Ni, Ni compound, W, W compound, and nitride.
